(19) United States
(12) Patent Application Publication
(10) Pub. No.: US 2004/0187791 A1
(43) Pub. Date: Sep. 30, 2004

(54) Mobile transportable electrostatic substrate holder

(76) Inventors: Karl-Hermann Busse, Wilnsdorf (DE); Steffen Keilbach, Siegen (DE)

Correspondence Address: Friedrich Kueffner, Suite 910, 317 Madison Avenue, New York, NY, 10017, US

(21) Appl. No.: 10/798,239

(22) Filed: Mar. 10, 2004

(30) Foreign Application Priority Data
Mar. 13, 2003 (DE) 203 04 124.0
Jul. 29, 2003 (DE) 203 11 625

(51) Int. Cl. C23C 16/00

(52) U.S. Cl. 118/728

(57) ABSTRACT

A mobile transportable electrostatic substrate holder is provided that has a diameter or edge length matching the diameter or edge length of a substrate to be transported. The tolerance of the matching dimensions, locally, at certain locations, or everywhere, is less than 0.1 mm. In another embodiment, the substrate holder has a diameter or edge length smaller by 0.1 mm to 30 mm, locally, at certain locations, or everywhere, than the diameter or edge length of the substrate to be transported. In a third embodiment, the substrate holder has a diameter or edge length that is greater by 0.1 mm up to 150 mm, locally, at certain locations, or everywhere, than the diameter or edge length of the substrate to be transported.

### BACKGROUND OF THE INVENTION

1. Field of the Invention

The invention relates to stationary electrostatic holders that have been in use for several years for manipulation of disk-shaped conducting or semi-conducting materials, in particular, as a holding device for manipulating so-called wafers in production facilities of the semiconductor industry.

2. Description of the Related Art

The operating principle is described in detail in publications such as: Sherman et al., Semiconductor International V 20 Jul. 1997, 319-321; Olson et al., Rev. Sci. Instrum. 66 (2) Feb. 1995, 1108-1114; Watanabe et al.: Jpn. J. Appl. Phys. Vol. (32) 1993, 864-71; Hartsough: Solid-State Technology, January 1993, 87-90.

The methods for applying these principles to so-called mobile transportable electrostatic holding systems are described in detail in European patent application 1 217 655 A1, U.S. patent publication 2002/0110449 A1, as well as WO 02/11184 A1; they represent the prior art.

The practical application of the methods for mobile electrostatic manipulation resulted in the development of first mobile electrostatic holding devices (so-called transfer ESCs, for short: T-ESCs) for electrostatic holding of film-like materials (for example, silicon wafers), in particular, for the semiconductor technology; compare European patent application 1 217 655 A1.

However, the first proposed solutions fulfill only unsatisfactorily many of the technical and economic requirements placed on such mobile electrostatic holders (substrate holders).

The cause for this resides in that the transportable electrostatic substrate holder are adapted only to a minimal extent to the different fields of application and processing steps during processing and manipulating wafers primarily in the semiconductor industry. The same holds true also for other important industrial areas, for example, solar technology, medical technology, and audio technology when handling thin substrates, for example, solar cells, filters, memory media. Many problems that are analog to those of the semiconductor technology are present.

### SUMMARY OF THE INVENTION

It is an object of the present invention to provide a mobile transportable electrostatic substrate holder (T-ESC) that can be used especially in the semiconductor industry but is also suitable for many other fields of application without having to be altered.

In accordance with the present invention, different embodiments of mobile transportable electrostatic substrate holders (T-ESCs) particular for use in the semiconductor industry are proposed that can be used in many cases also without alteration in other industrial branches.

In the semiconductor industry, the substrate holders according to the invention primarily reduce drastically the risk of yield loss, for example, because of breakage or mechanical destruction of the components.

In addition to the thickness of the mobile electrostatic substrate holders (compare in this regard European patent application 1 217 655 A1), another important parameter is the diameter. In order to reduce the edge breakage risk of the relatively brittle wafers, for example, of silicone or other semiconductor materials, e.g., gallium arsenide, in the semiconductor technology, it is generally beneficial to design the diameter of the substrate holder to have the same size as that of a standardized wafer (compare Semi Standard, for example, M1.9-0699) and to configure it to be substantially congruent to the already present wafer geometries, for example, round or angled (so-called flats, compared the pertinent Semi Standards).

For some processes, such as plasma etching, it is however expedient to reduce the diameter (circular, round substrates, optionally with so-called flats) or the outer dimensions (for example, the edge length in the case of polygonal substrates) of the mobile electrostatic substrate holder in comparison to the wafer by 0.1 mm up to 30 mm. In this way, on the one hand, in the case of minimal removal by etching, rounded edges are formed that can reduce the breakage risk of the wafer drastically, and, on the other hand, by means of the significantly reduced mobile electrostatic substrate holder in comparison to the transported wafer, the risk of electric breakdown to the mobile electrostatic substrate holder is reduced and also a fast erosion of the transfer ESCs in the plasma is prevented.

When, for holding the mobile electrostatic substrate holder, an additional fixedly mounted stationary electrostatic holding device is used, it is expedient to coat the side facing the stationary electrostatic substrate holder with metals (for example, aluminum, nickel) and/or semi-conductor materials (for example, silicon) and/or metal alloys (for example, nickel chromium alloys) locally, at certain locations, or everywhere in order to increase the adhesion of the mobile electrostatic substrate holders. If necessary, an additional electric potential can be applied thereto. In this way, unipolar and/or multi-polar electrodes can be formed at the back side.

A further possibility resides in that magnetic materials (for example, ferrites) are introduced massively (as a solid body) into the mobile electrostatic substrate holder or are coated locally, at certain locations, or everywhere with such a material. The substrate holder can then be secured magnetically by means of a receptacle (receiving device) correspondingly provided with magnets.

In other situations, where it is necessary to manipulate or/and secure the mobile electrostatic substrate holder loaded with the substrate (for example, wafer) mechanically, for example, by means of a gripping device or clamping device, it is expedient to configure the mobile electrostatic substrate holder locally, at certain locations, or across all outer geometries to be larger than the substrate to be transported (for example, wafer). Relative to the diameter or the outer dimensions of the substrate (for example, wafer having a diameter of 300 mm), the mobile electrostatic substrate holder can be larger by up to 150 mm. The projecting edge having a width of up to 150 mm can then be used for clamping or mechanical handling of the transportable electrostatic substrate holder that is loaded with the substrate (for example, wafer). By means of an additional clamping or protective ring that is provided locally, at certain locations, or circumferentially so as to cover the edge and is comprised of, for example, a plastic material such as polyamide or a ceramic material such as aluminum oxide, the projecting edge or rim of the mobile electrostatic substrate holder can be effectively protected against a plasma attack (FIG. 1a, 1b).

Moreover, the mechanical clamping action of the mobile electrostatic substrate holder in comparison to stationary electrostatic substrate holders that are fixedly mounted in the processing machine, enables a significant efficiency increase (productivity increase) of the processing machines. For example, in the semiconductor industry many processing machines, for example, for plasma etching, are currently furnished in general with fixedly mounted, stationary electrostatic holding systems.

The electric (electrostatic) charging and discharging of the electrostatic substrate holding system for attracting (charging) and releasing (discharging) the substrate (wafer), depending on the type of employed material for the dielectric of the electrostatic substrate holder (optionally enhanced by the so-called memory effect), size and dimensions of the wafer, can take up to approximately 20 seconds per processing chamber in the case of stationary electrostatic substrate holding devices according to the prior art. However, when the time-intensive charging and discharging process is carried out by using the described mobile electrostatic substrate holder of the present invention external to the processing machine (for example, plasma device) and the mobile substrate holder that is loaded with the wafer is introduced into the machine and mechanically secured and fixedly positioned therein by clamps, the throughput of the extremely expensive processing machines can be increased by approximately 5-25% (depending on the processing time). Accordingly, the clamping rings or clamping devices can be opened and closed very quickly, for example, by means of electric motors, pneumatic feeding devices etc., as has been known in the art for a long time. Such mechanical clamping devices have already been used at a time when stationary electrostatic substrate holders were not yet known or employed. However, they clamp the substrate (for example, wafer) and not, as described here, the mobile electrostatic substrate holder.

Since, according to the present invention, the wafers to be treated are not covered by the clamping ring, the size of the wafer surface to be processed matches the wafer surface to be treated when employing stationary electrostatic substrate holders, i.e., there is no yield loss as a result of covering of the wafer surface by the clamping ring, as in the case of prior art clamping devices. Also, this does not cause an increase of particle generation as is the case for purely mechanical clamping systems of the old type where undesirable particles are generated primarily at the interface or contact location wafer/clamping ring by opening and/or closing of the clamping ring and, for-example, as a result of tearing of contamination layers, for example, comprised of plasma polymers.

At the same time, the use of the mobile electrostatic substrate holder according to the invention decreases the consumption of operating supplies (gases etc.) per each processed substrate (wafer). Since the mobile electrostatic substrate holders can reach a similarly long service life as the expensive stationary electrostatic substrate holders that are rather complex regarding manufacturing technological aspects, but can be produced much less expensively, the maintenance costs can be lowered significantly.

The edge of the mobile electrostatic substrate holder that projects past the dimensions of the substrate (for example, wafer) can be configured to be thicker by up 30 mm and thinner up to 10 mm thinner than the area covered by the substrate, locally, at certain locations, or peripherally. This design feature enables, for example, in the case of increased thickness, as described in European patent application 1 217 655 A1, to arrange accumulators, batteries, complex electronic devices of larger dimensions within the mobile electrostatic substrate holders. On the other hand, a thin rim or edge simplifies mechanical clamping and centering of the mobile electrostatic holding systems within the processing machine.

Of course, as explained in connection with European patent application 1 217 655 A1, the accumulators, the electronic devices etc. can also be arranged in housings of different types that are locally always present or not always present. For example, flexible continuous or discontinuous automatic or manual manipulation, electrical charging and discharging of the mobile electrostatic substrate holder in so-called wafer carriers is enabled in this way.

Very high shearing forces occur in the field of the semiconductor industry in particular when grinding and polishing the wafers.

At high removal rates, the electrostatic holding force is often no longer sufficient in order to secure the wafer safely during the aforementioned mechanical processing steps.

At present, in grinding and polishing machines and also often in other atmospheric treatment devices, so-called vacuum holders (vacuum receptacles) are used in most cases for providing a fixation and a securing action for the wafer. For this purpose, a vacuum is generated on the back side of the wafer by means of a vacuum pump. In accordance with the respective pressure differential, the holding force can be up to approximately 0.1 N/mm².

In order to enable a uniform pressure distribution (holding force distribution), the vacuum holders (vacuum receptacles, wafer receptacles) are frequently comprised of (homogenous) porous materials or of disks that are provided with holes and are also annularly perforated (FIGS. 2a, 2b)

When however the mobile electrostatic substrate holder is perforated (FIGS. 2a, 2b) in the same way as the vacuum holder (vacuum receptacle) present in the grinding machine, polishing machine or atmospheric treatment machine (for example, also a spin etching device or various lithography devices), a significant component of the holding force generated by the vacuum holder (generated by the pressure difference) can be used for fixation of the wafer on the electrostatic substrate holder in addition to the electrostatic holding force.

In order to obtain a uniform action of the vacuum for securing the wafer and for preventing penetration of liquids, for example, grinding emulsions, acids for spin etching, it is expedient to provide the side facing and/or facing away from the-mobile electrostatic substrate holder (compare FIGS. 2a, 2b) with seals (sealing surfaces). They can be comprised, for example, of polymers such as silicones, fluoro-based plastic materials and/or of suitable metals, for example, electroplated nickel and/or metal alloys (primarily for higher temperatures).

These seals are usually provided in the outer area (FIG. 1a, 1b) of the mobile electrostatic substrate holder. In a similar way, additional seals of polymers and/or metals and/or metal-alloys can also be provided in the outer area of the vacuum receptacle in order to seal the intermediate space between the back side of the mobile electrostatic substrate holder and the vacuum receptacle (not illustrated in FIGS. 2a, 2b).

Mobile electrostatic substrate holders primarily for grinding, polishing, for photolithography and wet-chemical cleaning of substrates (wafers) should be comprised preferably of glass materials, glass ceramics, ceramic materials or semiconductor materials. They have on the one hand similar mechanical and physical properties as the materials (for example, silicon) processed in the semiconductor industry and can be calibrated, for example, in a grinding machine for wafer grinding (prior) with regard to the required flatness and plane-parallel configuration. On the other hand, they are usually excellent insulators or can be easily modified accordingly so that loss currents are small even in wet media.

Primarily the aforementioned ceramics or glass multi-layer technology and the use of glass materials that can be (photo)-structured—known inter alia by the trademark Foturan®—has been found to be very useful for producing electrostatic substrate holders, for example, for grinding and polishing. Also, by employing glass materials, transparent mobile electrostatic substrate holders can be produced that are suitable, for example, for optical adjustment of protective devices (packaging), for example, for micro-mechanical components (so-called MEMS).

Moreover, the multi-layer technology of plastic materials is recommended, as in the manufacture of printed circuits, for example, by employing chemically very resistant polyimide films for producing mobile electrostatic substrate holders for plasma etching, spin etching and for transport purposes.

In a comparable way, as described above, mobile electrostatic substrate holders can be provided also with perforations, seals, sealing elements and textures of the surface, respectively, for use in plasma etching, plasma-enhanced deposition from the gas phase (PECVD), plasma-enhanced physical deposition (PVD).

It is described in European patent application 1 217 655 A1 that a mobile electrostatic substrate holder can be used in order to positionally fix the workpiece during processing, for example, during plasma etching. The embodiments that are known presently are not designed to prevent the usually occurring heat development that is detrimental for the workpiece or the wafer by means of a cooling device.

Accordingly, in a further embodiment according to the invention of a mobile electrostatic substrate holder, the substrate holder has bores or perforations through which during processing of the wafer the occurring heat energy can be reduced by gas cooling, for example, by means of helium. In this case, the gas flow is guided through the bores (note: in the above text as well as in the following text, the term bores is to be understood not only to mean round bores but also openings or perforations of other geometries, for example, square, oval etc.) against the wafer such that a gas-filled intermediate space results between the aforementioned workpiece and the mobile electrostatic substrate holder.

An especially safe cooling action is achieved when the cooling gas is distributed, for example, from one or several usually centrally arranged bores in the electrostatic substrate holder through cooling gas channels provided in the front side of the mobile electrostatic substrate holder that is facing the back side of the wafer. These cooling gas channels facing the back side of the wafer can be embodied as disclosed in European patent application 0 948 042 A1 and in U.S. Pat. No. 6,215,641.

The bores or perforations of the mobile electrostatic substrate holder are also needed, in addition to their use as a conduit for the required cooling gas, in order to feed lifting pins, sensors, and contact pins against the wafer.

The lifting pins serve for lifting and placing the mobile electrostatic substrate holder loaded with substrate (wafer) off and/or onto the stationary receptacle (receiving device) or, when they or additional lifting pins are guided through perforations or bores through the mobile electrostatic substrate holder, also for lifting and placing the wafer onto the mobile electrostatic substrate holder secured on the receptacle (receiving device) (FIGS. 1a, 1b). Lifting is carried out so that the electrostatic substrate holder loaded with the substrate (wafer) or only the substrate (wafer) can be picked up and transported by means of a robot arm. In the same aforementioned way, it is possible to guide sensors, for example, temperature sensors, to the back side of the substrate (wafer) or the mobile electrostatic substrate holder. Moreover, contact pins can be guided to the back side of the mobile electrostatic substrate holder in order to electrically recharge it, if needed, in the respective processing machine. Recharging in the processing machine is necessary primarily when, as has been found in practice, long processing times or very high temperatures (>approximately 150° C.) are present that greatly favor undesirable electrical discharge of the mobile electrostatic substrate holder in the processing machine.

In the case that the mobile electrostatic substrate holder is configured based on semiconductors, and the so-called Johnson-Rahbek effect (or arrangement) is used, the loss currents are usually so high that an electrical recharging must be carried out in the processing machine, as mentioned above. Often the desired function can be ensured only in this way.

Since it is possible to electrically recharge in the processing machine or processing environment, a composite electrostatic holding system is provided that is combined of the mobile electrostatic substrate holder and the respective stationary receiving device; this composite electrostatic holding system, if needed, can be operated as long as and in the same way as a conventional, fixedly mounted electrostatic holding system that is comprised of one or several stationary parts.

Such a two-part or multi-part holding system according to the invention has the advantage in comparison to older conventional configurations that in the context of maintenance, for example, in vacuum devices for plasma etching, the maintenance can be carried out automatically by changing the (mobile) electrostatic substrate holder that is usually the part that is worn first by means of a manipulation robot present for wafer handling without the vacuum chamber having to be opened and flushed with the surrounding atmosphere. For this purpose, the mobile electrostatic substrate holders, with regard to geometry and dimensions, are to be designed similarly to the employed wafers so that special adaptations of the machine systems are not necessary (compare also European patent application 1 217 655 A1).

In conventional systems having prior art configuration, maintenance requires in general several hours for installing and demounting the stationary electrostatic holding system and for adjusting a stable operating state (in particular, a stable vacuum). Moreover, as already mentioned, mobile electrostatic holding systems can be produced significantly less expensively than the known stationary electrostatic holding systems.

The contact pins, when resting (because of bores, perforations etc. extending through the mobile electrostatic substrate holder) against the back side of the wafer, can also be used for electrical discharging of the wafer or the substrate (FIG. 1b). The aforementioned pins can comprise only individual ones, several, or all of the aforementioned functions; for example, they can be used as lifting pins, contact pins, as well as supports of sensors.

The perforations extending through the mobile electrostatic substrate holder are usually surrounded by additional seals (FIG. 1b) in order to prevent increased outflow of the cooling gas into the processing chamber.

In a preferred embodiment, the mobile electrostatic substrate holder, for example, in order to improve the cooling effect on the wafer, is provided with additional seals of polymers, for example, silicones, fluoro-plastic materials (for example, fluoro-elastomers) and/or metals (for example, nickel) and/or metal alloys (for example, nickel chromium alloys). These seals can be arranged on the side facing the wafer and/or on the back side facing away from the wafer on the mobile electrostatic substrate holder (FIGS. 3a to 3c).

The seals arranged on the back side of the mobile electrostatic substrate holder facing away from the wafer can be omitted when one or several seals are provided on the receptacle (receiving device) of the mobile electrostatic substrate holder (FIG. 3c).

By polishing, lapping, grinding, fine-turning or milling of the sealing surfaces of the mobile electrostatic substrate holder and/or the receptacle (receiving device), the gas tightness can be further improved.

If necessary, it is possible in this way to omit seals locally, at certain locations or everywhere in accordance with the pressure and environmental conditions.

A further improved configuration is shown in FIG. 4. In this configuration, the cooling gas (preferably helium) is introduced, for example, through the receptacle (receiving device), often cooled with deionized water or a glycol mixture, into an intermediate space formed together with the aforementioned substrate holder via one or several annular gas bores (FIG. 4). The helium cools first the back side of the mobile electrostatic substrate holder facing away from the wafer. Subsequently, the cooling gas is introduced (guided) into the intermediate space between the wafer and the mobile electrostatic substrate holder, for example, through one preferably centrally arranged bore or several bores.

In this way, the back side of the wafer is very effectively cooled.

By means of the gas channels (FIG. 3a) on the surface of the mobile electrostatic substrate holder or/and the receptacle (receiving device), the efficiency of the cooling action can be further increased.

On the outer edge of the wafer, if necessary, the cooling gas is returned by means of a vacuum device (FIG. 4). It can therefore be recycled and, if needed, after being cooled, can be reused. As a result of the additionally provided seals, the cooling gas cannot flow into the surrounding process chamber and cannot negatively affect the processing parameters required for plasma etching or cathode evaporation (PVD, sputtering).

In order to achieve an effective cooling of the wafer preferably by means of gases, a cooling surface area is required that is as large as possible. For example, a corresponding texturing of the front side of the mobile electrostatic substrate holder facing the wafer and/or facing away from the wafer as well as of the surface of the stationary receptacle (receiving device) is beneficial. Texturing can be provided, for example, by grinding, sawing, chemical etching, laser cutting (uniformly textured surface, so-called defined texturing) or, for example, by sandblasting (non-uniform textured surface, so-called undefined or random texturing) in combination with the aforementioned methods.

Preferred texturing has a uniform grid pattern (FIGS. 5a-5c). The surfaces produced in this way are further processed by additional polishing and/or lapping, mechanical treatment (grinding, fine-turning, milling). In this way, excellent flatness and plane-parallel configurations of the textured surfaces can be produced.

### BRIEF DESCRIPTION OF THE DRAWING

In the drawing:

FIG. 1a is a section of a complete electrostatic holding device according to the invention;

FIG. 1b is a section of the complete electrostatic holding device as shown in FIG. 1a but rotated by 90°;

FIG. 2a shows a plan view of a first embodiment of a mobile electrostatic substrate holder according to the invention;

FIG. 2b is a section view along section line IIb-IIb of the mobile electrostatic substrate holder according to FIG. 2a;

FIG. 3a shows a plan view of a second embodiment of a mobile electrostatic substrate holder according to the invention illustrating gas channels for distributing cooling gas;

FIG. 3b shows a section view along section line IIIb,c-IIIb,c of a mobile electrostatic substrate holder of FIG. 3a illustrating the position of the seals;

FIG. 3c shows a section view along section line IIIb,c-IIIb,c of a mobile electrostatic substrate holder of FIG. 3a illustrating seals in different positions in comparison to FIG. 3b;

FIG. 4 shows a section of the electrostatic substrate holder secured by a clamping ring on a receptacle;

FIG. 5a illustrates non-uniform (random) surface texturing in section;

FIG. 5b illustrates uniform surface texturing in section; and

FIG. 5c illustrates the desired grid pattern of the surface texturing in a plan view.

### DESCRIPTION OF THE PREFERRED EMBODIMENTS

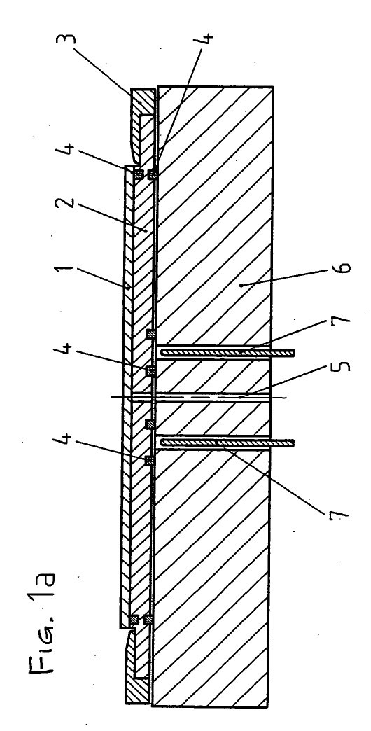

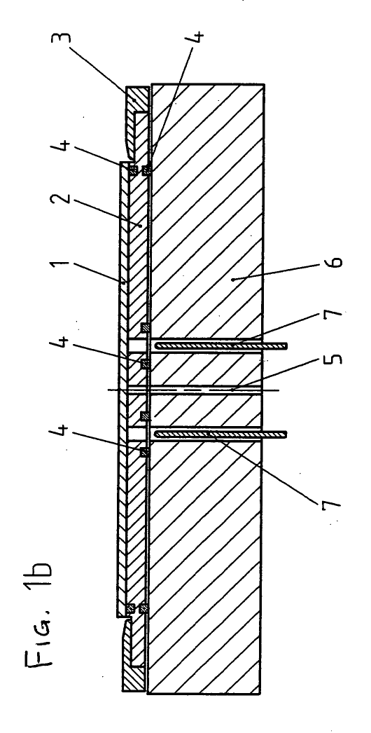

FIG. 1a describes a section of a complete electrostatic holding device, for example, for plasma etching, according to this invention. Reference numeral 1 is a substrate (wafer), reference numeral 2 is the mobile electrostatic substrate holder, reference numeral 3 is the clamping ring with which the mobile electrostatic substrate holder 2 is secured.

Peripheral seals 4 are provided in the mobile electrostatic substrate holder 2 in order to prevent lateral flow of the gases provided for the gas cooling action of the substrate (wafer) 1.

Additional seals 4 about the bore(s) for the lifting pins or contact pins 7 for the mobile electrostatic substrate holder 2 reduce additionally the leakage flows of the cooling gas. The bore 5 is the bore for the gas cooling action (for example, centrally arranged as shown). The stationary receptacle (receiving device) 6, provided optionally with cooling and heating devices, passages for cooling gases, lifting pins and suitable contact pins 7 for electrical charging and/or discharging, and sensors, receives the mobile electrostatic substrate holder 2 with the substrate (wafer) 1. By means of the lifting and contact pins 7 the mobile electrostatic substrate holder 2 that secures the substrate (wafer) 1 is lifted off the stationary receiving device 6 or placed onto it or/and electrically charged or discharged.

Like FIG. 1a, FIG. 1b shows a section of a complete electrostatic holding device, for example, for plasma etching, according to this invention but the section of FIG. 1b is rotated by 90° in comparison to the section of FIG. 1a. The description is substantially identical to that of FIG. 1a; the difference is that the illustrated additional lifting and contact pins 7 are used only for lifting (lowering) or for electrical contacting (primarily discharging) of the substrate (wafer) 1.

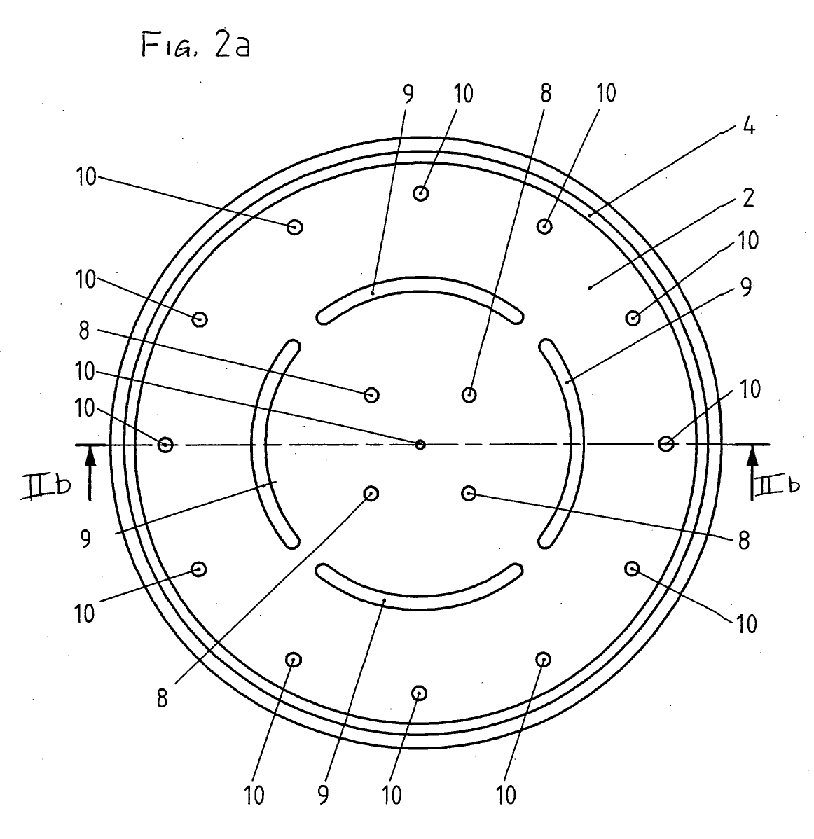

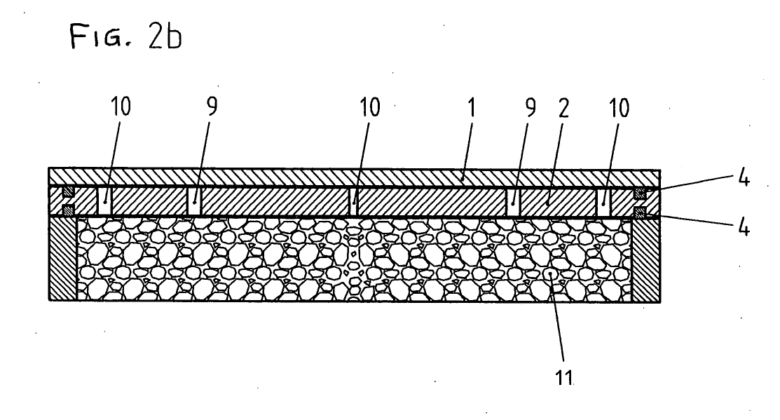

The FIG. 2a shows in a plan view a proposed embodiment according to the invention for a mobile electrostatic substrate holder 2 that is suitable, for example, for grinding and polishing. For simplifying the illustration, the substrate (wafer) is not shown. In addition to the bores 8 for the lifting and contacting pins 7, the mobile electrostatic substrate holder 2 has an annular perforation 9 as well as a row of additional bores 10 in order to be able to use the vacuum that is generated by means of the vacuum receptacle 11 (compare FIG. 2b) in addition to the electrostatic holding force for the fixation and securing action of the substrate (wafer) 1. Moreover, FIG. 2a shows the peripheral seal 4.

FIG. 2b shows a section of FIG. 2a. In order to simplify the illustration, the view is shown without lifting or contact pins. The vacuum receptacle 11, manufactured of a porous, for example, ceramic material, secures by means of vacuum the mobile electrostatic substrate holder 2 that secures, in turn, the substrate (wafer) 1 electrostatically and by means of the generated vacuum. Moreover, FIG. 2b shows the peripheral seals 4 that, on the one hand, keep a leakage flow, detrimental for the vacuum, at a minimum and, on the other hand, prevent penetration of grinding and polishing agents as well as possibly present liquids (for example, grinding emulsions). Moreover, FIG. 2b shows also in exemplary fashion an annular perforation 9 as well as the bores 10 in the mobile electrostatic substrate holder 2 required for the additional vacuum securing action.

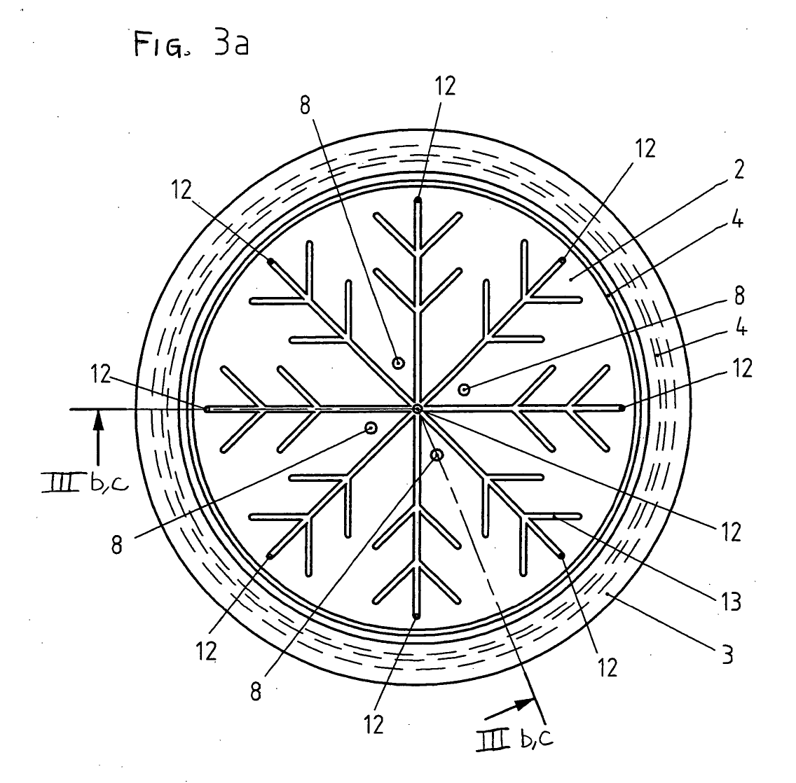

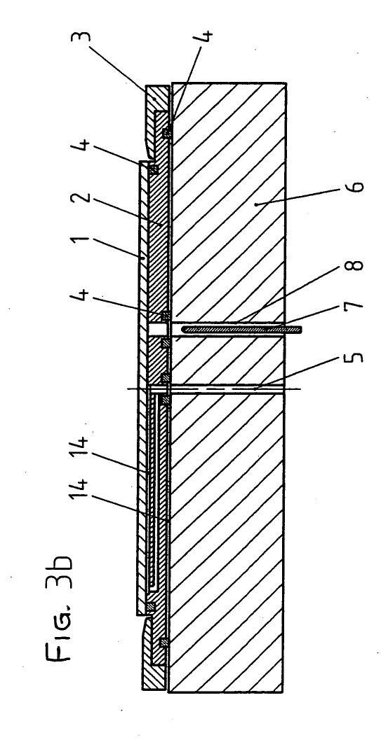

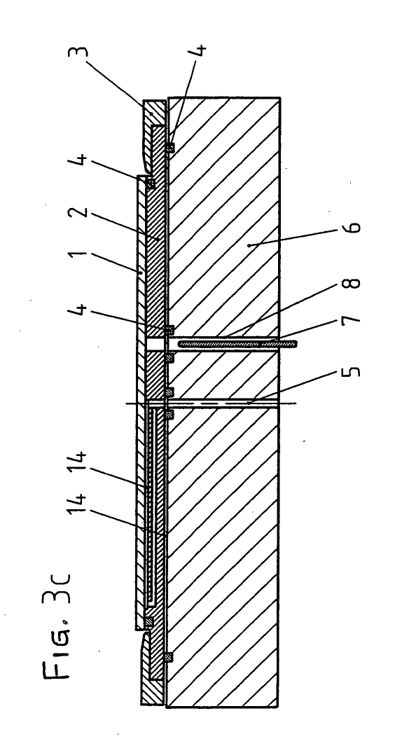

The FIGS. 3a-3c disclose in a plan view (FIG. 3a) and in section (3b, 3c) different ways of sealing mobile electrostatic substrate holders 2, for example, for plasma etching, in order to achieve leakage flows as minimal as possible.

FIG. 3a shows in a plan view a structured surface for gas distribution 13 by means of gas channels of the mobile electrostatic substrate holder 2. In order to facilitate the illustration, the substrate (wafer) 1 is not shown.

The mobile electrostatic substrate holder 2 is secured by the clamping ring 3. Moreover, the illustration shows (one) central and radial bore(s) for cooling gas distribution 12 as well as seals 4 and bores 8 for the lifting and contact pins 7.

FIG. 3b shows a section of FIG. 3a. Seals 4 are arranged in recesses provided in the mobile electrostatic substrate holder 2. In this way, the back side of the substrate (wafer) 1 as well as the back side of the mobile electrostatic substrate holder 2 facing away from the substrate (wafer) 1 and the individual bores 8 for the lifting and contacting pins 7 are sealed. The clamping ring 3 secures the mobile electrostatic substrate holder 2. The bore 5 for gas cooling continues into the stationary receptacle (receiving device) 6. By means of the employed seals 4 between the substrate (wafer) 1 and the mobile electrostatic substrate holder 2 as well as between the stationary receptacle 6, sealed, highly effective intermediate spaces 14 are provided for cooling the substrate (wafer) 1.

FIG. 3c shows an additional section of FIG. 3a illustrating a further proposal according to the invention. The description is essentially identical to that of FIG. 3b. In deviation therefrom, the seals 4 are also arranged in recesses in the stationary receptacle 6 of the mobile electrostatic substrate holder 2.

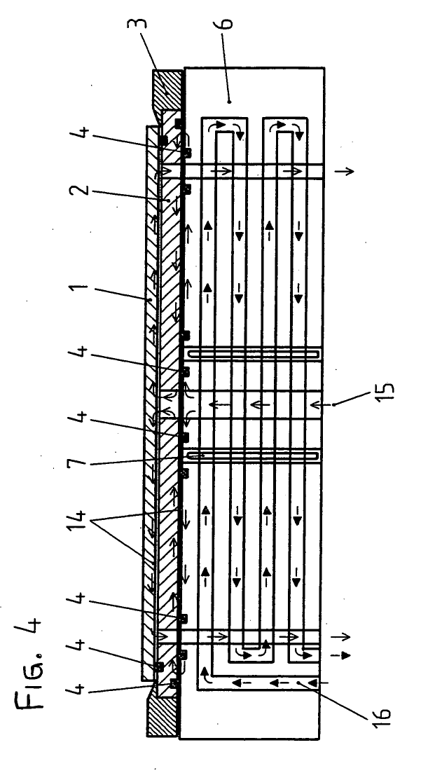

FIG. 4 shows in section a further part of the invention. The mobile electrostatic substrate holder 2 is secured by a clamping ring 3 on the receptacle (receiving device) 6. The mobile electrostatic substrate holder 2 secures the substrate (wafer) 1. As a result of the seals or sealing surfaces arranged in the recesses of the mobile electrostatic substrate holder 2 and the stationary receptacle (receiving device) 6, the intermediate spaces 14 for providing the required gas cooling action are realized. By means of the indicated cooling gas flow 15 that flows in the intermediate spaces 14 and the liquid cooling action 16 in the stationary receptacle (receiving device) 6, a very efficient cooling of the substrate (wafer) 1 is achieved. With a closed circulation of the cooling gas corresponding to the illustrated cooling gas flow 15 the cooling gas can be reused and, if necessary, properly temperature-controlled (cooled or heated).

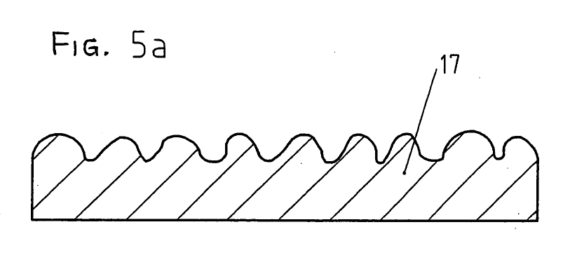

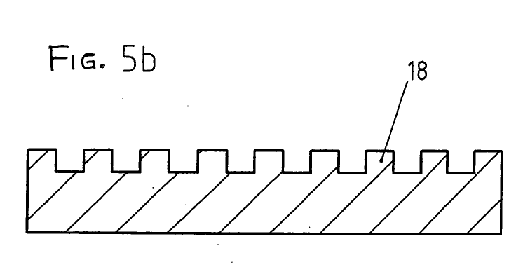

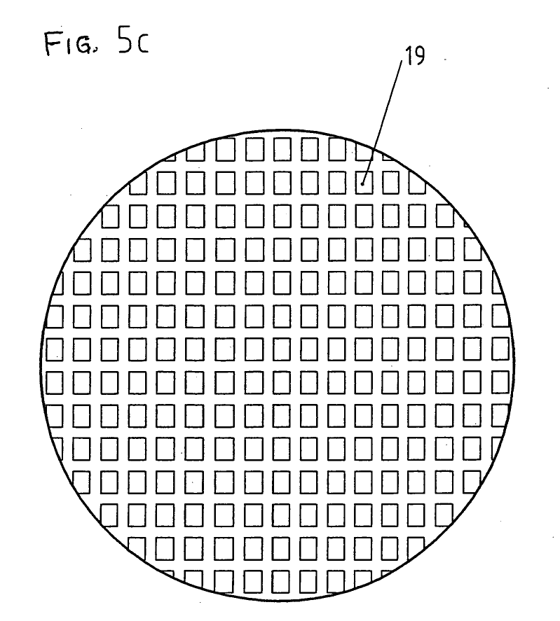

FIGS. 5a-5c show a proposed embodiment according to another aspect of the invention for improving the cooling action of the cooling gas by generating a cooling surface as large as possible on one or both sides (the side facing or facing away from the substrate (wafer) 1) of the mobile electrostatic substrate holder 2 or/and the stationary receptacle 6.

FIG. 5a shows as an example a textured surface 17 that is produced by sandblasting and is non-uniform (undefined, random). It has in comparison to a uniform (defined) textured surface 18 according to FIG. 5b the advantage of a surface area that is usually much larger and is economically beneficial with regard to its manufacture.

The uniformly textured (defined) surface 18 illustrated in FIG. 5b, which can be produced, for example, by means of reproducible mechanical methods (for example, milling, sawing, grinding) and by means of beam methods carried out with the aid of laser beam, electron beam or by means of chemical methods (for example, wet-etching or dry-etching (plasma etching)), enables substantially more homogenous cooling properties in comparison to the treated surfaces according to FIG. 5a.

FIG. 5c shows in a plan view the desired grid pattern 19 of the surfaces according to FIGS. 5a and 5b produced by the texturing methods. By means of surface grinding, lapping, polishing, milling or fine-turning of the textured surfaces 17, 18, a grid pattern 19 according to FIG. 5c of the treated surface and an excellent flatness and plane-parallel configuration of the mobile electrostatic substrate holder 2 and the stationary receptacle (receiving device) 6 for the mobile electrostatic substrate holder 2 is achieved.

While specific embodiments of the invention have been shown and described in detail to illustrate the inventive principles, it will be understood that the invention may be embodied otherwise without departing from such principles.

What is claimed is:

1. A mobile transportable electrostatic substrate holder, having a diameter and/or edge lengths matching a diameter and/or edge lengths of a substrate to be transported with a tolerance of less than 0.1 mm, locally, at certain locations, or everywhere.

2. A substrate holder according to claim 1, wherein an exposed area of the substrate holder that is not covered by the substrate to be transported is up to 30 mm thicker or up to 10 mm thinner, locally, at certain locations, or everywhere, than a covered area of the substrate holder covered by the substrate.

3. A substrate holder according to claim 1, having one or several holes and/or perforations in order to increase a holding force of the substrate holder acting on the substrate by utilizing the substrate holder simultaneously as a vacuum holder.

4. The substrate holder according to claim 1, wherein the substrate holder and/or a receptacle for the substrate holder has one or several bores and/or perforations for passing a gas therethrough for cooling the substrate and/or for passing lifting and/or contact pins and/or sensors therethrough.

5. The substrate holder according to claim 1, wherein the substrate holder and/or the substrate is electrically charged and/or electrically discharged inside or outside of a processing machine through contact pins.

6. The substrate holder according to claim 1, wherein the substrate holder and/or the substrate is moveable by lifting pins.

7. The substrate holder according to claim 1, wherein in a front side of the substrate holder facing the substrate and/or in both sides of the substrate holder and/or in a surface of a receptacle of the substrate holder, one or several channels are provided that are connected to one or several bores for passing a cooling gas flow therethrough.

8. The substrate holder according to claim 1, wherein the substrate has a front side facing the substrate and a back side facing away from the substrate, wherein the back side and/or the front side has one or several sealing surfaces and/or seals.

9. The substrate holder according to claim 1, comprising seals comprised of solid polymers and/or solid metals or comprised of coatings made of polymers and/or metals, wherein the seals are provided locally or at several locations.

10. The substrate holder according to claim 1, wherein between the substrate and the substrate holder and/or between a receptacle for the substrate holder and the substrate holder one or several intermediate spaces are present for cooling with a cooling gas.

11. The substrate holder according to claim 1, wherein a cooling gas is guided in a circuit and is reusable.

12. The substrate holder according to claim 1, wherein in a receptacle for the substrate holder one or several sealing surfaces and/or seals are provided.

13. The substrate holder according to claim 1, having a front side facing the substrate and a back side, wherein at least one of the front side and the back side of the substrate holder and/or a receptacle for the substrate holder is textured by sawing, milling, turning, grinding and/or cutting, for example, by laser beam and/or electron beam, wet-chemical etching, plasma etching, or sandblasting, preferably in a grid shape, in order to provide a cooling surface area as large as possible for a cooling gas.

14. The substrate holder according to claim 13, wherein the front side and/or the back side of the substrate holder and/or the receptacle is machined by grinding and/or lapping and/or polishing or milling or turning in order to generate flatness and a plane-parallel configuration.

15. The substrate holder according to claim 1, having a front side facing the substrate and a back side, wherein in at least one of the front side and the back side of the substrate holder locally, at certain locations, or everywhere one or several magnetic metals and/or non-magnetic metals, metal alloys and/or metalloids are introduced in the form of solid bodies and/or the front side and/or the back side of the substrate holder are coated locally, at certain locations or everywhere with one or several magnetic metals and/or non-magnetic metals, metal alloys and/or metalloids.

16. The substrate holder according to claim 1, having a front side facing the substrate and a back side, wherein in at least one of the front side and the back side one or several unipolar or/and multi-polar electrodes are present.

17. The substrate holder according to claim 1, wherein a receptacle for the substrate holder comprises one or several magnets.

18. The substrate holder according to claim 1, manufactured by glass multi-layer technology and/or ceramic multi-layer technology and/or plastic multi-layer technology.

19. The substrate holder according to claim 1, comprised of at least one of the materials selected from the group consisting of ceramics, glass material, photo-texture glass, glass ceramics, semiconductor materials, and plastic materials, and further comprising metals and/or metal alloys.

20. The substrate holder according to claim 1, having a front side facing the substrate and a back side, wherein at least one of the front side and the back side and/or a receptacle for the substrate holder is fine-machined by at least one of polishing, grinding, lapping, milling, and turning for achieving a high gas seal-tightness.

21. The substrate holder according to claim 1, configured to be electrically supplied, electrically charged and/or electrically discharged continuously or discontinuously.

22. A mobile transportable electrostatic substrate holder, having a diameter and/or edge lengths smaller by 0.1 mm to 30 mm, locally, at certain locations, or everywhere, than a diameter and/or edge lengths of a substrate to be transported.

23. A substrate holder according to claim 22, wherein an exposed area of the substrate holder that is not covered by the substrate to be transported is up to 30 mm thicker or up to 10 mm thinner, locally, at certain locations, or everywhere, than a covered area of the substrate holder covered by the substrate.

24. A substrate holder according to claim 22, having one or several holes and/or perforations in order to increase a holding force of the substrate holder acting on the substrate by utilizing the substrate holder simultaneously as a vacuum holder.

25. The substrate holder according to claim 22, wherein the substrate holder and/or a receptacle for the substrate holder has one or several bores and/or perforations for passing a gas therethrough for cooling the substrate and/or for passing lifting and/or contact pins and/or sensors therethrough.

26. The substrate holder according to claim 22, wherein the substrate holder and/or the substrate is electrically charged and/or electrically discharged inside or outside of a processing machine through contact pins.

27. The substrate holder according to claim 22, wherein the substrate holder and/or the substrate is moveable by lifting pins.

28. The substrate holder according to claim 22, wherein in a front side of the substrate holder facing the substrate and/or in both sides of the substrate holder and/or in a surface of a receptacle of the substrate holder, one or several channels are provided that are connected to one or several bores for passing a cooling gas flow therethrough.

29. The substrate holder according to claim 22, wherein the substrate has a front side facing the substrate and a back side facing away from the substrate, wherein the back side and/or the front side has one or several sealing surfaces and/or seals.

30. The substrate holder according to claim 22, comprising seals comprised of solid polymers and/or solid metals or comprised of coatings made of polymers and/or metals, wherein the seals are provided locally or at several locations.

31. The substrate holder according to claim 22, wherein between the substrate and the substrate holder and/or between a receptacle for the substrate holder and the substrate holder one or several intermediate spaces are present for cooling with a cooling gas.

32. The substrate holder according to claim 22, wherein a cooling gas is guided in a circuit and is reusable.

33. The substrate holder according to claim 22, wherein in a receptacle for the substrate holder one or several sealing surfaces and/or seals are provided.

34. The substrate holder according to claim 22, having a front side facing the substrate and a back side, wherein at least one of the front side and the back side of the substrate holder and/or a receptacle for the substrate holder is textured by sawing, milling, turning, grinding and/or cutting, for example, by laser beam and/or electron beam, wet-chemical etching, plasma etching, or sandblasting, preferably in a grid shape, in order to provide a cooling surface area as large as possible for a cooling gas.

35. The substrate holder according to claim 34, wherein the front side and/or the back side of the substrate holder and/or the receptacle is machined by grinding and/or lapping and/or polishing or milling or turning in order to generate flatness and a plane-parallel configuration.

36. The substrate holder according to claim 22, having a front side facing the substrate and a back side, wherein in at least one of the front side and the back side of the substrate holder locally, at certain locations, or everywhere one or several magnetic metals and/or non-magnetic metals, metal alloys and/or metalloids are introduced in the form of solid bodies and/or the front side and/or the back side of the substrate holder are coated locally, at certain locations or everywhere with one or several magnetic metals and/or non-magnetic metals, metal alloys and/or metalloids.

37. The substrate holder according to claim 22, having a front side facing the substrate and a back side, wherein in at least one of the front side and the back side one or several unipolar or/and multi-polar electrodes are present.

38. The substrate holder according to claim 22, wherein a receptacle for the substrate holder comprises one or several magnets.

39. The substrate holder according to claim 22, manufactured by glass multi-layer technology and/or ceramic multi-layer technology and/or plastic multi-layer technology.

40. The substrate holder according to claim 22, comprised of at least one of the materials selected from the group consisting of ceramics, glass material, photo-texture glass, glass ceramics, semiconductor materials, and plastic materials, and further comprising metals and/or metal alloys.

41. The substrate holder according to claim 22, having a front side facing the substrate and a back side, wherein at least one of the front side and the back side and/or a receptacle for the substrate holder is fine-machined by at least one of polishing, grinding, lapping, milling, and turning for achieving a high gas seal-tightness.

42. The substrate holder according to claim 22, configured to be electrically supplied, electrically charged and/or electrically discharged continuously or discontinuously.

43. A mobile transportable electrostatic substrate holder, having a diameter and/or edge lengths greater by 0.1 mm up to 150 mm, locally, at certain locations, or everywhere, than a diameter and/or edge lengths of a substrate to be transported.

44. A substrate holder according to claim 43, wherein an exposed area of the substrate holder that is not covered by the substrate to be transported is up to 30 mm thicker or up to 10 mm thinner, locally, at certain locations, or everywhere, than a covered area of the substrate holder covered by the substrate.

45. A substrate holder according to claim 43, having one or several holes and/or perforations in order to increase a holding force of the substrate holder acting on the substrate by utilizing the substrate holder simultaneously as a vacuum holder.

46. The substrate holder according to claim 43, wherein the substrate holder and/or a receptacle for the substrate holder has one or several bores and/or perforations for passing a gas therethrough for cooling the substrate and/or for passing lifting and/or contact pins and/or sensors therethrough.

47. The substrate holder according to claim 43, wherein the substrate holder and/or the substrate is electrically charged and/or electrically discharged inside or outside of a processing machine through contact pins.

48. The substrate holder according to claim 43, wherein the substrate holder and/or the substrate is moveable by lifting pins.

49. The substrate holder according to claim 43, wherein in a front side of the substrate holder facing the substrate and/or in both sides of the substrate holder and/or in a surface of a receptacle of the substrate holder, one or several channels are provided that are connected to one or several bores for passing a cooling gas flow therethrough.

50. The substrate holder according to claim 43, wherein the substrate has a front side facing the substrate and a back side facing away from the substrate, wherein the back side and/or the front side has one or several sealing surfaces and/or seals.

51. The substrate holder according to claim 43, comprising seals comprised of solid polymers and/or solid metals or comprised of coatings made of polymers and/or metals, wherein the seals are provided locally or at several locations.

52. The substrate holder according to claim 43, wherein between the substrate and the substrate holder and/or between a receptacle for the substrate holder and the substrate holder one or several intermediate spaces are present for cooling with a cooling gas.

53. The substrate holder according to claim 43, wherein a cooling gas is guided in a circuit and is reusable.

54. The substrate holder according to claim 43, wherein in a receptacle for the substrate holder one or several sealing surfaces and/or seals are provided.

55. The substrate holder according to claim 43, having a front side facing the substrate and a back side, wherein at least one of the front side and the back side of the substrate holder and/or a receptacle for the substrate holder is textured by sawing, milling, turning, grinding and/or cutting, for example, by laser beam and/or electron beam, wet-chemical etching, plasma etching, or sandblasting, preferably in a grid shape, in order to provide a cooling surface area as large as possible for a cooling gas.

56. The substrate holder according to claim 55, wherein the front side and/or the back side of the substrate holder and/or the receptacle is machined by grinding and/or lapping and/or polishing or milling or turning in order to generate flatness and a plane-parallel configuration.

57. The substrate holder according to claim 43, having a front side facing the substrate and a back side, wherein in at least one of the front side and the back side of the substrate holder locally, at certain locations, or everywhere one or several magnetic metals and/or non-magnetic metals, metal alloys and/or metalloids are introduced in the form of solid bodies and/or the front side and/or the back side of the substrate holder are coated locally, at certain locations or everywhere with one or several magnetic metals and/or non-magnetic metals, metal alloys and/or metalloids.

58. The substrate holder according to claim 43, having a front side facing the substrate and a back side, wherein in at least one of the front side and the back side one or several unipolar or/and multi-polar electrodes are present.

59. The substrate holder according to claim 43, wherein a receptacle for the substrate holder comprises one or several magnets.

60. The substrate holder according to claim 43, manufactured by glass multi-layer technology and/or ceramic multi-layer technology and/or plastic multi-layer technology.

61. The substrate holder according to claim 43, comprised of at least one of the materials selected from the group consisting of ceramics, glass material, photo-texture glass, glass ceramics, semiconductor materials, and plastic materials, and further comprising metals and/or metal alloys.

62. The substrate holder according to claim 43, having a front side facing the substrate and a back side, wherein at least one of the front side and the back side and/or a receptacle for the substrate holder is fine-machined by at least one of polishing, grinding, lapping, milling, and turning for achieving a high gas seal-tightness.

63. The substrate holder according to claim 43, configured to be electrically supplied, electrically charged and/or electrically discharged continuously or discontinuously.
